(19) United States
(12) Patent Application Publication
(10) Pub. No.: US 2018/0062652 A1
(43) Pub. Date: Mar. 1, 2018

(54) HARDENED STORAGE ELEMENT

(71) Applicant: STMicroelectronics (Crolles 2) SAS, Crolles (FR)

(72) Inventors: Fady Abouzeid, Grenoble (FR); Gilles Gasiot, Seyssinet-Pariset (FR)

(21) Appl. No.: 15/443,779

(22) Filed: Feb. 27, 2017

(30) Foreign Application Priority Data
Aug. 31, 2016 (FR) 1658080

(51) Int. Cl. H03K 19/003; H03K 3/356

(52) U.S. Cl. CPC H03K 19/00338; H03K 3/356104

(57) ABSTRACT

A storage element including two CMOS inverters, coupled head-to-tail between two nodes; and one MOS transistor, connected as a capacitor between said nodes.

### BACKGROUND

### Technical Field

The present disclosure relates to an electronic circuit, and more particularly, to a storage element hardened against random logic events.

### Description of the Related Art

A storage element is for example formed of a flip-flop, comprising two CMOS inverters coupled head-to-tail between two nodes. The state of a storage element of this type is likely to be modified by a random logic event, for example, by a radiation which causes a current peak in one of the nodes of the storage element, which may cause a logic error.

U.S. Pat. No. 7,109,541 of the applicant describes a device enabling to make a storage element comprising CMOS inverters more robust to random logic events. FIG. 1, which corresponds to FIG. 4 of U.S. Pat. No. 7,109,541, is an electric diagram of the device. This device comprises two CMOS inverters 1 and 2 coupled head-to-tail between two nodes 4 and 5, and two capacitors 7 and 8 series-connected between nodes 4 and 5. The connection point of the two capacitors forms a node which is inevitably capacitively coupled to ground by a stray capacitance 9.

The presence of capacitors 7, 8, and 9 makes nodes 4 and 5 capacitive. Thus, when a current peak occurs on node 4 or 5, this peak is strongly attenuated. Capacitances 7 and 8 are selected by taking into account the current peaks likely to be applied to the circuit in its context of use. The greater the risk for significant peaks to occur, the stronger the capacitance should be used to attenuate them down to a value smaller than the state switching threshold of the storage element.

### BRIEF SUMMARY

An embodiment provides a circuit robust to random logic events which does not require using strong capacitances.

An embodiment provides such a circuit having a surface area close to that of a non-hardened circuit.

Thus, an embodiment provides a storage element comprising two CMOS inverters, coupled head-to-tail between two nodes; and one MOS transistor, connected as a capacitor between said nodes.

According to an embodiment, the drain and the source of said transistor are interconnected.

According to an embodiment, said transistor connected as a capacitor comprises four first transistors connected in parallel.

According to an embodiment, two of the four first transistors are N-channel transistors, identical to the N-channel transistors of the inverters, and the two other first transistors are P-channel transistors, identical to the P-channel transistors of the inverters.

According to an embodiment, one of the first N-channel transistors and one of the first P-channel transistors have their gates connected to the input of a first inverter and their drain/source connected to the output thereof, and the two other first transistors have their gates connected to the input of the second inverter and their drain/source connected to the output thereof.

According to an embodiment, one of the inverters is a clocked inverter.

According to an embodiment, a storage element comprises a substrate with a P-type active area and an N-type active area for each inverter; four first transistors, each formed in one of the active areas; four second transistors, two N-channel transistors and two P-channel transistors, corresponding to the transistors of the two CMOS inverters, each being formed in a different active area and being connected by its drain to the drain and to the source of the first transistor formed on this area; two conductive strips, each forming and connecting the gates of the first and second transistors of an active P-type area and of an active N-type area; and two metallizations, each connecting the drains of four transistors connected by a conductive strip; the sources of one P-channel transistor and of one N-channel transistor from among these four transistors; and the conductive strip connecting the gates of the four other transistors.

The foregoing and other features and advantages will be discussed in detail in the following non-limiting description of specific embodiments in connection with the accompanying drawings.

### BRIEF DESCRIPTION OF THE SEVERAL VIEWS OF THE DRAWINGS

FIG. 1, previously described, is an electric diagram of a storage element resistant to radiation;

FIG. 2 shows an electric diagram of a storage element;

FIG. 3 is a top view of a layout of a portion of the storage element of FIG. 2;

FIG. 4 shows the detailed electric diagram of an embodiment of a hardened storage element;

FIGS. 5A, 5B, and 5C are current and voltage timing diagrams;

FIG. 6 shows in further detail an embodiment of a hardened storage element; and

FIG. 7 is a top view of a layout of a portion of the hardened storage element of FIG. 6; and

FIG. 8 is a top view of a layout of another portion of the hardened storage element of FIG. 6.

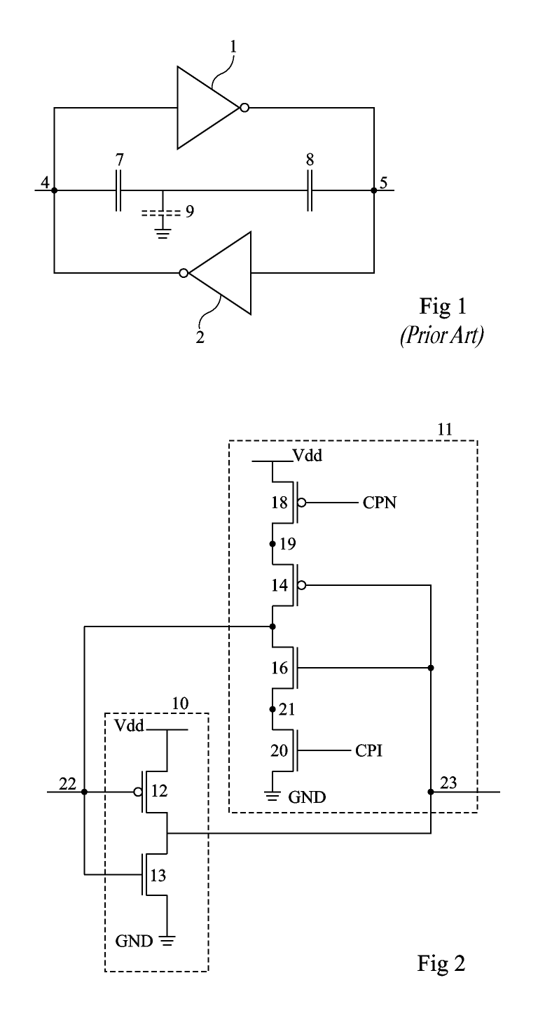

### DETAILED DESCRIPTION

The same elements have been designated with the same reference numerals in the various drawings and, further, the drawings illustrating layouts are not to scale. For clarity, only those steps and elements which are useful to the understanding of the described embodiments have been shown and are detailed.

In the timing diagrams, the voltage values are given in millivolts, the current values are given in microamperes, and the times are given in nanoseconds.

FIG. 2 is an electric diagram of a storage element, comprising two CMOS inverters 10 and 11 coupled head-to-tail between two nodes.

Inverter 10 comprises a P-channel transistor 12 and an N-channel transistor 13. A supply source Vdd is connected to the source of transistor 12. The drain of transistor 12 is connected to the drain of transistor 13, forming the output node of inverter 10. The source of transistor 13 is connected to a ground GND. The gates of transistors 12 and 13 are interconnected and form the input node of inverter 10.

Inverter 11 is a clocked inverter and comprises a P-channel transistor 14 and an N-channel transistor 16. The gates of transistors 14 and 16 are interconnected and form the input node of inverter 11. The drain of transistor 14 is connected to the drain of transistor 16, forming the output node of inverter 11. The source of transistor 14 is connected to the drain of a transistor 18 identical to transistor 14. This connection forms a node 19. The source of transistor 18 is connected to supply source Vdd. The source of transistor 16 is connected to the drain of a transistor 20 identical to transistor 16. This connection forms a node 21. The source of transistor 20 is connected to ground GND. The access nodes of the storage elements are nodes 22 and 23. The gates of transistors 18 and 20 are respectively capable of receiving complementary clock signals CPN and CPI. The gate connections of transistors 14 and 18 on the one hand, 16 and 20 on the other hand, may be inverted without affecting the functionality of the device.

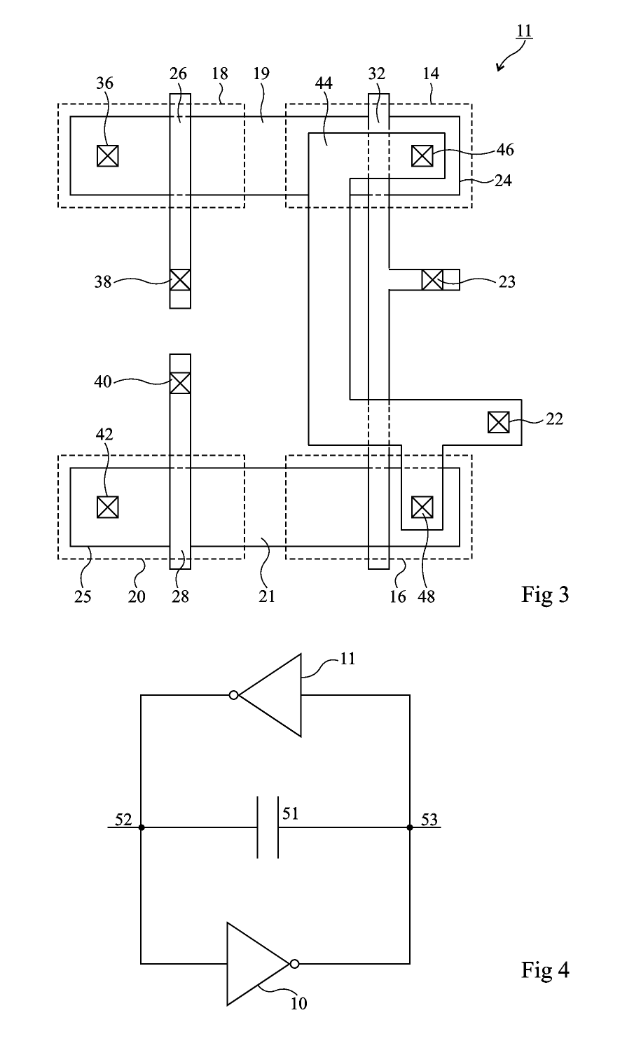

FIG. 3 is a simplified top view of a layout of clocked inverter 11 of FIG. 2. P-channel transistors 14 and 18 are formed in a P-type active area 24. The drain area of transistor 18 and source area of transistor 14 corresponds to node 19. Similarly, N-channel transistors 16 and 20 are formed in an active N-type area 25. The drain area of transistor 20 and source area of transistor 16 corresponds to node 21. A conductive strip 26, currently polysilicon, forms the gate of transistor 18 and a conductive strip 28 forms the gate of transistor 20. A conductive strip 32 forms the gates of transistors 14 and 16. Gate strip 32 is connected to a via representing input node 23 of inverter 11. The source of transistor 18 is connected to the supply source Vdd by a via 36. The gate of transistor 18 is connected by a via 38 to a source of signal CPN. The gate of transistor 20 is connected by a via 40 to a source of signal CPI. The source of transistor 20 is connected to the low power supply source by a via 42. Vias 46 and 48, connected by a metallization 44, create the connection between the drains of transistors 14 and 16. A via representing node 22 connected to metallization 44 forms the output node of inverter 11.

FIG. 4 is an electric diagram of an embodiment of a hardened storage element. The storage element comprises the two CMOS inverters 10 and 11. It further comprises a capacitor 51 connected between first and second access nodes 52 and 53 of the storage element.

Conversely to the device of U.S. Pat. No. 7,109,541, where a voltage peak on an access node is almost totally absorbed by capacitors 7, 8, and 9, the single capacitor 51 of the embodiment of FIG. 4 transfers the voltage peak occurring on one of the first and second nodes 52 and 53 to the other node.

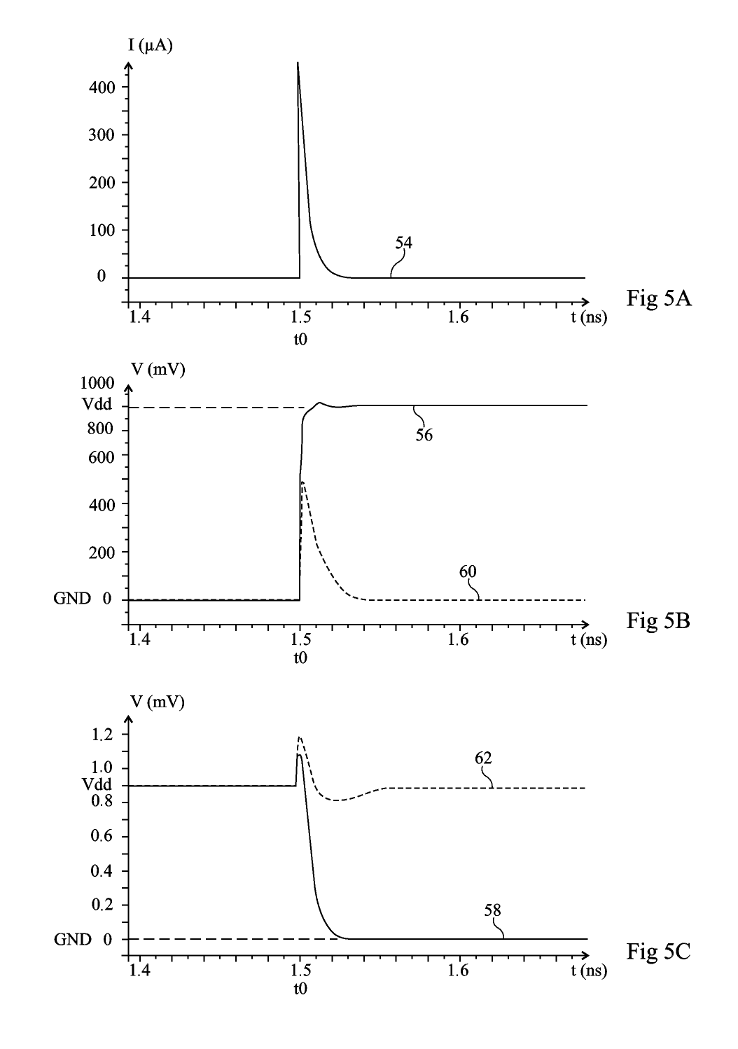

FIGS. 5A to 5C show the effect of a positive current peak 54 resulting in a voltage peak and occurring on first access node 52 of a flip-flop of a storage element in the case where the first access node is at 0 (GND) and the second access node is at 1 (Vdd).

Curves 56 and 58 illustrate the case of FIG. 2 where the storage element is not hardened. Under the effect of voltage peak 54, the first terminal switches to 1 (Vdd) and the second terminal accordingly switches to 0 (GND). The state of the storage element is inverted.

Curves 60 and 62 illustrate the case of a storage element of the type of the storage element illustrated in FIG. 4. Voltage peak 54 on node 52 tends to cause the switching of inverter 10. However, the voltage peak transferred to node 53 increases the voltage of node 53 and thus reinforces state 1 of this node, opposing the switching of inverter 10. The output of inverter 10 remains at 1 and the state of the storage element is maintained.

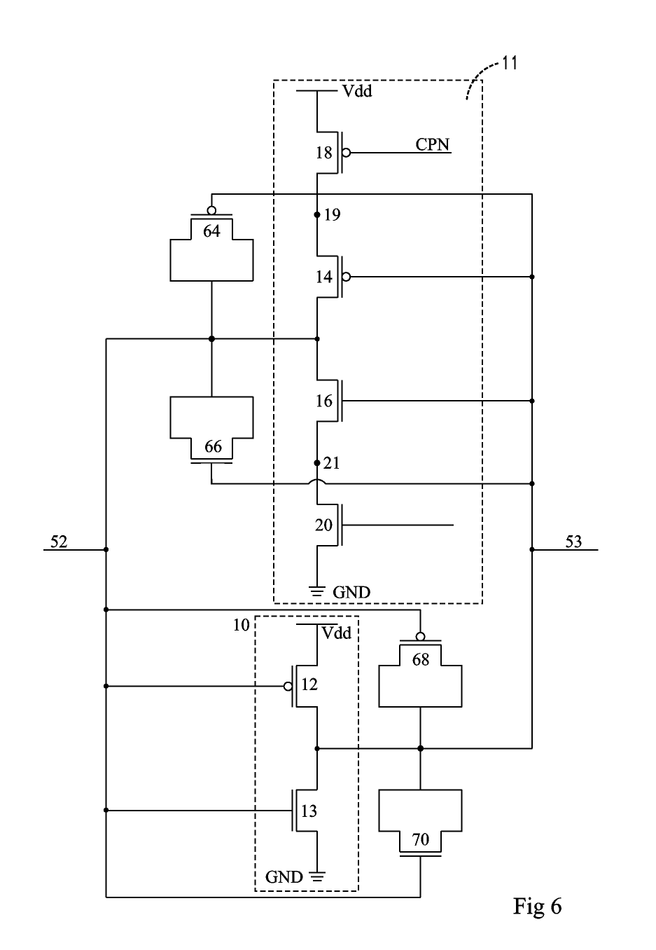

FIG. 6 shows in further detail an embodiment of the hardened storage element of FIG. 4. The storage element comprises inverters 10 and 11 as described in relation with FIG. 2. It also comprises capacitors 64, 66, 68, and 70 in the form of transistors. Transistors 64 and 68 are P-channel transistors and transistors 66 and 70 are N-channel transistors. The P-channel transistors of the storage element are all identical to one another. Similarly, the N-channel transistors of the storage element are all identical to one another. The first terminal of each capacitor 64, 66, 68, and 70 is formed by the transistor gate. The second terminal is formed by the source and the drain of the transistor connected to each other. The first terminals of capacitors 64 and 66 are connected to the input (node 53) of inverter 11, the second ones are connected to the output thereof (node 52). Similarly, the first terminals of capacitors 68 and 70 are connected to the input (node 52) of inverter 10, the second ones are connected to the output thereof (node 53). One can thus find, between nodes 52 and 53 of the storage element, four transistors in parallel which correspond to the single capacitor of FIG. 4.

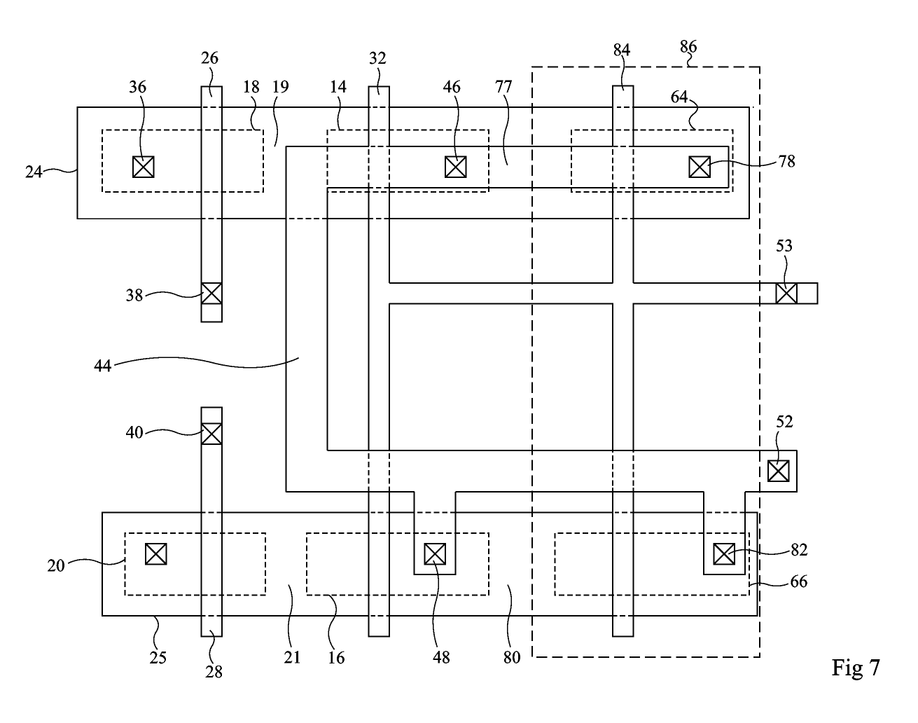

FIG. 7 is a simplified top view of a layout of inverter 11 and of transistors 64 and 66 connected as capacitors described in relation with FIG. 6. The elements which have already been described are not described again. Transistor 64 is formed in active area 24 and transistor 66 is formed in active area 25. An area 77 forms the connection between the source of transistor 64 and the drain of transistor 14. A via 78 connects the drain of transistor 64 to metallization 44 and thus to the source of transistor 64 and to the drain of transistor 14. Similarly, an area 80 forms the connection between the source of transistor 66 and the drain of transistor 16. A via 82 connects the drain of transistor 66 to metallization 44 and thus to the source of transistor 66 and to the drain of transistor 16. A conductive strip 84 forms the gate of transistors 64 and 66 and is connected to strip 32. Thus, the gates of transistors 14, 16, 64, and 66 are interconnected and the drains and the sources of transistors 64 and 66 are connected to the drains of transistors 14 and 16.

The selection of transistors 64 to 70 identical to the transistors of the inverter provides a layout which adds but little surface area to the surface area of the storage element of FIG. 3. Indeed, only those elements contained in the frame in dotted lines 86 have been added in the layout of FIG. 7 as compared with the layout of FIG. 3. For a complete storage element, the surface area increase with respect to the storage element described in FIGS. 2 and 3 is smaller than 20%.

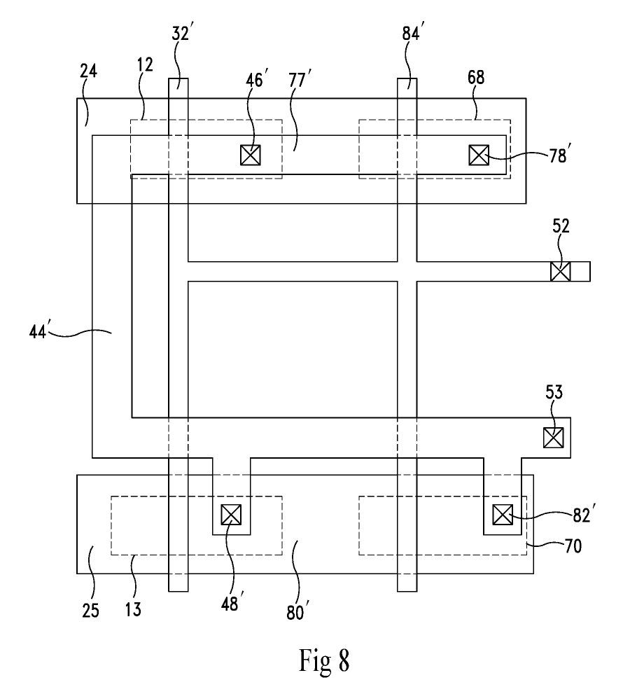

FIG. 8 is a simplified top view of a layout of inverter 10 and of transistors 68 and 70 connected as capacitors described in relation with FIG. 6. The P-channel transistor 12 may be formed in the active area 24 and the N-channel transistor 13 may be formed in the active area 25. The drain area of transistor 18 and source area of transistor 14 corresponds to node 19. Gate strip 32′ is connected to a via representing the node 52. The source of transistor 12 is connected to the supply source Vcc by a via (not shown). The source of transistor 13 is connected to the ground GND by another via (not shown). Vias 46′ and 48′, connected by a metallization 44′, create the connection between the drains of transistors 12 and 13. A via representing node 53 connected to metallization 44′ forms the output node of inverter 10.

Transistor 68 is formed in active area 24 and transistor 70 is formed in active area 25. An area 77′ forms the connection between the source of transistor 68 and the drain of transistor 12. A via 78′ connects the drain of transistor 68 to a metallization 44′ and thus to the source of transistor 68 and to the drain of transistor 12. Similarly, an area 80′ forms the connection between the source of transistor 70 and the drain of transistor 13. A via 82′ connects the drain of transistor 70 to metallization 44′ and thus to the source of transistor 70 and to the drain of transistor 13. A conductive strip 84′ forms the gate of transistors 68 and 70 and is connected to a strip 32′. Thus, the gates of transistors 12, 13, 68, and 70 are interconnected and the drains and the sources of transistors 68 and 70 are connected to the drains of transistors 12 and 13.

Although FIG. 8 shows the transistors of the CMOS inverter and the transistors 68, 70 in the same active areas 24, 25 the transistors shown in FIG. 7, the transistors 12, 13, 68, 70 could be formed in different active areas. Also, metallization 44′ could simply be an extension of the conductive strips 32, 84 and the conductive strips 32′, 84′ could simply be an extension of the metallization 44.

Specific embodiments have been described. Various alterations, modifications, and improvements will occur to those skilled in the art. In particular, the inverters forming the storage elements may be of a different type than those described in FIG. 2. Similarly, the transistors connected as capacitors are not limited in their number and channel type to the transistors described in FIG. 6. Finally, FIGS. 3 and 7 only illustrate examples of storage element layouts. These may vary according to the types of storage element which are desired to be hardened and to the technologies used.

Such alterations, modifications, and improvements are intended to be part of this disclosure, and are intended to be within the spirit and the scope of the present disclosure. Accordingly, the foregoing description is by way of example only and is not intended to be limiting.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A storage element comprising:
first and second CMOS inverters coupled head-to-tail between first and second nodes; and
a first MOS transistor, connected as a capacitor, and coupled between said first and second nodes.

2. The storage element of claim 1, wherein said first MOS transistor includes a source and a drain that are interconnected to each other.

3. The storage element of claim 1, further comprising second, third and fourth MOS transistors, each connected as a capacitor, wherein said first, second, third, and fourth MOS transistors are connected in parallel.

4. The storage element of claim 3, wherein:
each of the first and second CMOS inverters includes an N-channel transistor and a P-channel transistor;
the first and second MOS transistors are N-channel transistors, substantially identical to the N-channel transistors of the first and second CMOS inverters, and
the third and fourth MOS transistors are P-channel transistors, substantially identical to the P-channel transistors of the first and second CMOS inverters.

5. The storage element of claim 4, wherein:
each of the first, second, third, and fourth MOS transistors includes a source and a drain, which are interconnected to each other, and a gate;
the gates of the first and third MOS transistors are connected to an input of the first CMOS inverter and the drain and source of the first and third MOS transistors are connected to an output of the first CMOS inverter; and
the gates of the second and fourth MOS transistors are connected to an input of the second CMOS inverter and the drain and source of the second and fourth MOS transistors are connected to an output of the second CMOS inverter.

6. The storage element of claim 5, comprising:
a substrate with a P-type active area and an N-type active area, wherein:
the first and second MOS transistors are formed in the N-type active area; and
the third and fourth MOS transistors are formed in the P-type active area.

7. The storage element of claim 6, wherein:
the N-channel transistors of the first and second CMOS inverters are formed in the N-type active area and the P-channel transistors of the first and second CMOS inverters are formed in the P-type active area.

8. The storage element of claim 7, comprising:
a first conductive strip forming and connecting the gates of the N-channel and P-channel transistors of the first CMOS inverter and the gates of the first and third MOS transistors; and
a second conductive strip forming and connecting the gates of the N-channel and P-channel transistors of the second CMOS inverter and the gates of the second and fourth MOS transistors.

9. The storage element of claim 8, comprising:
a first metallization connecting the drains and sources of the first and third MOS transistors and the drains of the P-channel transistor and N-channel transistor of the first CMOS inverter; and
a second metallization connecting the drains and sources of the second and fourth MOS transistors and the drains of the P-channel transistor and N-channel transistor of the second CMOS inverter.

10. The storage element of claim 1, wherein one of the first and second CMOS inverters is a clocked inverter.

11. A flip-flop comprising:
first and second CMOS inverters coupled head-to-tail between first and second nodes; and
a first MOS transistor having a gate, source drain, the gate being connected to said first node and the source and drain being connected to each other and to the second node.

12. The flip-flop of claim 11, further comprising second, third and fourth MOS transistors, each connected as a capacitor, wherein said first, second, third, and fourth MOS transistors are connected in parallel.

13. The flip-flop of claim 12, wherein:
each of the first and second CMOS inverters includes an N-channel transistor and a P-channel transistor;
the first and second MOS transistors are N-channel transistors, substantially identical to the N-channel transistors of the first and second CMOS inverters, and
the third and fourth MOS transistors are P-channel transistors, substantially identical to the P-channel transistors of the first and second CMOS inverters.

14. The flip-flop of claim 13, wherein:
each of the second, third, and fourth MOS transistors includes a source and a drain, which are interconnected to each other, and a gate;
the gates of the first and third MOS transistors are connected to an input of the first CMOS inverter and the drain and source of the first and third MOS transistors are connected to an output of the first CMOS inverter; and
the gates of the second and fourth MOS transistors are connected to an input of the second CMOS inverter and the drain and source of the second and fourth MOS transistors are connected to an output of the second CMOS inverter.

15. The flip-flop of claim 14, comprising:
a first conductive strip forming and connecting the gates of the N-channel and P-channel transistors of the first CMOS inverter and the gates of the first and third MOS transistors; and
a second conductive strip forming and connecting the gates of the N-channel and P-channel transistors of the second CMOS inverter and the gates of the second and fourth MOS transistors.

16. The flip-flop of claim 15, comprising:
a first metallization connecting the drains and sources of the first and third MOS transistors and the drains of the P-channel transistor and N-channel transistor of the first CMOS inverter; and
a second metallization connecting the drains and sources of the second and fourth MOS transistors and the drains of the P-channel transistor and N-channel transistor of the second CMOS inverter.

17. The storage element of claim 1, wherein one of the first and second CMOS inverters is a clocked inverter.

18. A storage element comprising:
first and second CMOS inverters coupled head-to-tail between first and second nodes;
a first N-channel transistor having a gate connected to said first node and source and drain connected to each other and to the second node;
a second N-channel transistor having a gate connected to said second node and source and drain connected to each other and to the first node;
a first P-channel transistor having a gate connected to said first node and source and drain connected to each other and to the second node; and
a second P-channel transistor having a gate connected to said second node and source and drain connected to each other and to the first node.

19. The storage element of claim 18, wherein:
each of the first and second CMOS inverters includes an N-channel transistor and a P-channel transistor;
the N-channel transistors of the first and second CMOS inverters are substantially identical to the first and second N-channel transistors; and
the P-channel transistors of the first and second CMOS inverters are substantially identical to the first and second P-channel transistors.

20. The storage element of claim 5, comprising:
a substrate with a P-type active area and an N-type active area, wherein the first and second N-channel transistors are formed in the N-type active area, the first and second P-channel transistors are formed in the P-type active area, the N-channel transistors of the first and second CMOS inverters are formed in the N-type active area and the P-channel transistors of the first and second CMOS inverters are formed in the P-type active area;
a first conductive strip forming and connecting the gates of the N-channel and P-channel transistors of the first CMOS inverter and the gates of the first and third MOS transistors;
a second conductive strip forming and connecting the gates of the N-channel and P-channel transistors of the second CMOS inverter and the gates of the second and fourth MOS transistors;
a first metallization connecting the drains and sources of the first and third MOS transistors and the drains of the P-channel transistor and N-channel transistor of the first CMOS inverter; and
a second metallization connecting the drains and sources of the second and fourth MOS transistors and the drains of the P-channel transistor and N-channel transistor of the second CMOS inverter.
